(19) United States
(12) Patent Application Publication
(10) Pub. No.: US 2005/0061247 A1
(43) Pub. Date: Mar. 24, 2005

(54) Substrate processing apparatus, and combined system of functional blocks for use in substrate processing apparatus

(75) Inventors: Shuji Shibata, Kyoto (JP); Yoshihisa Yamada, Kyoto (JP); Masayoshi Shiga, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 10/946,954

(22) Filed: Sep. 22, 2004

(30) Foreign Application Priority Data
Sep. 22, 2003 (JP) 2003-329417

(51) Int. Cl. C23C 16/00

(52) U.S. Cl. 118/719

(57) ABSTRACT

A substrate processing apparatus is mechanically divided into processing blocks including an indexer block 1, a BARC block 2, a resist coating block 3, a development block 4, an interface block 5 and an inspection block IB. These processing blocks each comprise a transport robot and a substrate holding part which together serve as a substrate transport mechanism. The substrate holding parts of the processing blocks all have the same structure. The transport robot in each of the processing blocks is accessible to the substrate holding part belonging to an adjacent block.

### BACKGROUND OF THE INVENTION

1. Field of the Invention

The present invention relates to a substrate processing apparatus for performing a predetermined process such as application of a resist solution or development on a substrate which may be a semiconductor wafer or a glass substrate for a liquid crystal display, for example. The present invention more specifically relates to a substrate processing apparatus capable of inspecting the situation in the predetermined process.

2. Description of the Background Art

In the photolithography technique as one of manufacturing processes of a semiconductor device, a resist is applied onto the surface of a semiconductor substrate (hereinafter simply referred to as a “substrate”), and the applied resist is formed into a predetermined pattern by means of exposure. The patterned resist is thereafter subjected to development to form a resist film with the predetermined pattern. A series of these process steps is realized by a system with a connection of a substrate processing apparatus responsible for coating and development (which is a so-called coater and developer), and an exposure device.

A substrate subjected to substrate processing may generally require various types of substrate inspections. There has been a trend in recent years to use an automatic inspection apparatus capable of automatically performing these inspections. By way of example, inspections performed in the automatic inspection apparatus mainly include measurement of the thickness of an applied resist (inspection of resist film thickness), detection of the presence or absence of surface damage, unevenness in an applied resist or admixture of foreign substances during application of a resist solution (macroscopic defect inspection), measurement of the critical dimension of a resist pattern formed on a substrate (CD inspection), overlay inspection between the upper layer portion and the lower layer portion of a resist pattern, and the like. The CD and overlay inspections are carried out after exposure and development. The inspection of resist film thickness and the macroscopic defect inspection are usually carried out immediately after resist coating and before exposure, whereas they may be performed after exposure and development in some cases.

The automatic inspection apparatus has conventionally been arranged separately from the foregoing substrate processing apparatus as an independent unit with a combination of a plurality of inspection devices. Hence, a substrate should be transported to the automatic inspection apparatus to be subjected to a certain inspection therein, thereby causing difficulty in inspecting the situation of development in real time as well as complexity of transport. Further, this automatic inspection apparatus disadvantageously requires an additional unit to reduce particles in the environment where the automatic inspection apparatus is placed.

In response, a substrate processing apparatus equipped with the automatic inspection apparatus has been proposed. Japanese Patent Application Laid-Open No. 2002-26107 introduces an example of such a conventional substrate processing apparatus with the configuration shown in FIG. 7. The substrate processing apparatus of FIG. 7 comprises a cassette station S1 for storing semiconductor substrates (wafers) W, an inspection station S2 equipped with an automatic inspection apparatus, a first processing station S6 responsible for application of a resist solution, a second processing station S7 responsible for development, and an interface station S4 for transferring a substrate W between the second processing station S7 and an exposure device S5. As shown in FIG. 7, the inspection station S2 is arranged between the first and second processing stations S6 and S7, and the exposure device S5 is connected to the substrate processing apparatus. That is, in a direction from the cassette station S1 toward the exposure device S5, the cassette station S1, the first processing station S6, the inspection station S2, the second processing station S7, the interface station S4 and the exposure device S5 are arranged in this order.

According to such arrangement, a substrate W follows a transport path starting from the cassette station S1, then entering the first processing station S6 (for resist coating), the inspection station S2 (for inspection after resist coating), the second processing station S7, the interface station S4 and the exposure device S5 (for exposure), thereafter reentering the interface station S4, the second processing station S7 (for development), the inspection station S2 (for inspection after exposure) and the first processing station S6, finally returning to the cassette station S1. Namely, a substrate W can be subjected to inspection after resist coating and inspection after exposure, without going against the flow of transport starting from the cassette station S1, then moving forward to reach the exposure device S5, thereafter returning to the cassette station S1. Hence, a process flow requiring substrate inspection is simplified, thereby providing improved throughput of the substrate processing apparatus.

The detailed structure of each station constituting the substrate processing apparatus of FIG. 7 will be discussed. The cassette station S1 comprises a cassette 22 for storing substrates W, and a transport arm 23 having accessibility to the cassette 22 and the first processing station S6 and being responsible for transport of a substrate W. The two processing stations (first and second processing stations S6 and S7) each have a substrate processing part responsible for a predetermined substrate process (a coating unit 42 in the first processing station S6 and a development unit 41 in the second processing station S7), cabinet units R1 through R3 each including a thermal processor and a transfer part, and a substrate transport mechanism MA2 accessible to the substrate processing part and the cabinet units R1 through R3 in the same processing station. The interface station S4 has a transport arm A having accessibility to the second processing station S7 and the exposure device S5, and being responsible for transport of a substrate W.

Next, it will be discussed how a substrate W is transferred between the stations of the substrate processing apparatus shown in FIG. 7. With regard to transfer between the cassette station S1 and the first processing station S6, the transport arm 23 in the cassette station S1 transfers a substrate W onto and takes a substrate W from the transfer part of the cabinet unit R1 in the first processing station S6. With regard to transfer between the first processing station S6 and the inspection station S2, a substrate transport mechanism MA1 in the inspection station S2 transfers a substrate W onto and takes a substrate W from the transfer part of the cabinet unit R2 in the first processing station S6. With regard to transfer between the inspection station S2 and the second processing station S7, the substrate transport mechanism MA1 in the inspection station S2 transfers a substrate W onto and takes a substrate W from the transport part of the cabinet unit R1 in the second processing station S7. With regard to transfer between the second processing station S7 and the interface station S4, the transport arm A in the interface station S4 transfers a substrate W onto and takes a substrate W from the transport part of the cabinet unit R2 in the second processing station S7.

What is notable is that only the substrate transport mechanism MA1 in the inspection station S2 is responsible for transfer of a substrate W between the first and second processing stations S6 and S7. Hence, transfer of a substrate W between the first and second processing stations S6 and S7 is not allowed if the inspection station S2 is detached from the substrate processing apparatus of FIG. 7 to arrange the first and second processing stations S6 and S7 in a contiguous manner, for example. That is, the substrate processing apparatus of FIG. 7 necessarily requires the inspection station. S2 between the first and second processing stations S6 and S7.

As discussed, a substrate W can be subjected to predetermined substrate processes, inspection after resist coating and inspection after exposure, without going against the flow of transport starting from the cassette station S1, then moving forward to reach the exposure device S5, thereafter returning to the cassette station S1. On the other hand, in the event that substrate inspection only requires inspection after exposure, for example, the arrangement shown in FIG. 7 is not necessarily required in a theoretical sense.

As an example, when the cassette station S1, the inspection station S2, the first processing station S6, the second processing station S7, the interface station S4 and the exposure device S5 are arranged in this order in a direction from the cassette station S1 toward the exposure device S5, a substrate W can be theoretically subjected to a predetermined processes and inspection after exposure as well without going against the foregoing flow of transport. In this arrangement, a substrate W follows a transport path starting from the cassette station S1, then entering the inspection station S2, the first processing station S6 (for resist coating), the second processing station S7, the interface station S4 and the exposure device S5 (for exposure), thereafter reentering the interface station S4, the second processing station S7 (for development), the first processing station S6 and the inspection station S2 (for inspection after exposure), finally returning to the cassette station S1. This layout however locates the first and second processing stations S6 and S7 in a contiguous manner thus preventing transfer of a substrate W therebetween as discussed, and hence, is not feasible.

As another example, in the event that no substrate inspection is required and thus no inspection is performed at the inspection station S2, the inspection station S2 may be removed theoretically. In this case, the first and second processing stations S6 and S7 are also contiguously arranged thus preventing transfer of a substrate W therebetween. Removal of the inspection station S2 is unfeasible accordingly. Hence, if the inspection station S2 is detached from one substrate processing apparatus to be incorporated into another substrate processing apparatus, the former substrate processing apparatus without the inspection station S2 is inoperable.

For the reasons given above, the conventional substrate processing apparatus as shown in FIG. 7 does not allow flexibility in changing the arrangement of an inspection station. Hence, considerable constraints have been imposed on the layout change to be responsive to the object of substrate inspection, a substrate process flow or user's request, which in some cases hinders throughput improvement.

As discussed, the substrate processing apparatus shown in FIG. 7 without an inspection station is inoperable, which also obstructs layout change. That is, the substrate processing apparatus of FIG. 7 necessarily requires an inspection station, which possibly restricts cost reduction and footprint reduction of a system as a whole. Further disadvantageously, an inspection unit cannot be shared between a plurality of conventional substrate processing apparatuses.

### SUMMARY OF THE INVENTION

In a substrate processing apparatus to which an automatic substrate inspection apparatus is connectable, it is an object of the present invention to enhance flexibility of layout thereby realizing throughput improvement and cost reduction. It is also an object of the present invention to provide a combined system of functional blocks for use in such a substrate processing apparatus.

In a substrate processing apparatus according to the present invention, a first and a second edge structures are defined which are attached to or detached from each other while being complementarily coupled to each other by a butt joint, thereby realizing a certain boundary structure for substrate transfer.

Preferably, according to a first aspect of the substrate processing apparatus of the present invention, the substrate processing apparatus of the present invention comprises: a first substrate processing block; a second substrate processing block; and a substrate inspection block, wherein at least one of the first and second substrate processing blocks, and the substrate inspection block have respective substrate transport mechanisms, wherein a specific edge of the first substrate processing block has the first edge structure, wherein a specific edge of the second substrate processing block has the second edge structure, and wherein the substrate inspection block has a first edge with the first edge structure and a second edge with the second edge structure. Accordingly, the substrate processing apparatus is still operable when the substrate inspection block is detached therefrom, which contributes to cost reduction and footprint reduction of a substrate processing system as a whole. Further, the inspection block can be shared between a plurality of substrate processing apparatuses.

Preferably, according to a second aspect of the substrate processing apparatus of the present invention, the substrate processing apparatus of the first aspect further comprises: an additional substrate processing block having a first edge with the first edge structure and a second edge with the second edge structure, wherein the additional substrate processing block is interposed either between the substrate inspection block and the first substrate processing block or between the substrate inspection block and the second substrate processing block, whereby block interconnection is made by means of the butt joint between the first and second edge structures. Flexibility of layout is enhanced accordingly in the substrate processing apparatus, and throughput improvement is realized by layout change to be responsive to the object of substrate inspection or a substrate process flow, for example.

Preferably, according to a third aspect of the substrate processing apparatus of the present invention, the substrate processing apparatus of the first aspect further comprises: a plurality of additional substrate processing blocks each having a first edge with the first edge structure and a second edge with the second edge structure, wherein one or more of the plurality of additional substrate processing blocks are interposed either between the substrate inspection block and the first substrate processing block or between the substrate inspection block and the second substrate processing block, or both, whereby block interconnection is made by means of the butt joint between the first and second edge structures. Flexibility of layout is enhanced accordingly in the substrate processing apparatus, and throughput improvement is realized by layout change to be responsive to the object of substrate inspection or a substrate process flow, for example.

Preferably, according to a fourth aspect of the substrate processing apparatus of the present invention, in the substrate processing apparatus of the first aspect, the first edge structure has a substrate holding part arranged at a location accessible from a substrate transport mechanism when the first and second edge structures are connected, the substrate transport mechanism being contained in a block to which the second edge structure belongs. As a result, a substrate can be transferred between the substrate inspection block and the substrate processing block connected thereto.

Preferably, according to a fifth aspect of the substrate processing apparatus of the present invention, in the substrate processing apparatus of the fourth aspect, the substrate transport mechanism in the substrate inspection block includes a transport robot accessible to a substrate holding part in the first edge structure of the first substrate processing block when the first edge structure of the first substrate processing block is connected to the second edge structure of the substrate inspection block. As a result, a substrate can be transferred between the substrate inspection block and the substrate processing block connected thereto.

Preferably, according to a sixth aspect of the substrate processing apparatus of the present invention, in the substrate processing apparatus of the first aspect, the substrate inspection block comprises a substrate inspection unit responsible for a predetermined substrate process, and the substrate inspection unit is slidable in a horizontal direction. As a result, maintenance of the substrate inspection block can be facilitated.

According to a seventh aspect of the substrate processing apparatus of the present invention, in the substrate processing apparatus of the sixth aspect, the substrate inspection unit can be pulled out of the casing frame of the substrate inspection block by means of the slidable movement in a horizontal direction. As a result, maintenance of the substrate inspection block can be facilitated.

According to an eighth aspect of the substrate processing apparatus of the present invention, in the substrate processing apparatus of the first aspect, the substrate inspection block further comprises an inspection-specific buffer capable of temporarily storing a substrate to be subjected to inspection. As a result, throughput improvement is realized in the substrate processing apparatus.

According to a ninth aspect of the substrate processing apparatus of the present invention, in the substrate processing apparatus of the first aspect, the substrate inspection block further comprises an operating part for controlling substrate inspection at the substrate inspection block. As a result, an operator is always allowed to control operation of the substrate inspection unit near the inspection block even when arrangement of the inspection block is changed in the substrate processing apparatus.

According to a tenth aspect of the substrate processing apparatus of the present invention, in the substrate processing apparatus of the first aspect, either the first substrate processing block or the second substrate processing block is an indexer block for taking out an unprocessed substrate while storing a processed substrate. As a result, a substrate can be subjected to inspection without going against the flow of substrate transport.

According to an eleventh aspect of the substrate processing apparatus of the present invention, in the substrate processing apparatus of the first aspect, one of the first and second substrate processing blocks is a resist coating block for forming a resist film on a substrate, and the other one of the first and second substrate processing blocks is a development block for performing development upon a substrate. As a result, a substrate can be subjected to inspection after resist coating and inspection after exposure and development without going against the flow of substrate transport.

A combined system of functional blocks of the present invention is intended for use in a substrate processing apparatus. In this system, a first and a second edge structures are defined as a pair which are attached to or detached from each other while being complementarily coupled to each other by a butt joint, thereby realizing a certain boundary structure for substrate transfer.

Preferably, according to a first aspect of the combined system of functional blocks of the present invention, the combined system of functional blocks of the present invention comprises: a plurality of substrate processing blocks; and a substrate inspection block, wherein butt joints between the plurality of substrate processing blocks, and a butt joint between each of the plurality of substrate processing blocks and the substrate inspection block are each formed by the connection of the first and second edge structures as a pair, whereby an arbitrary combination is applicable including two or more of the plurality of substrate processing blocks and the substrate inspection block. Accordingly, the substrate processing apparatus is still operable when the substrate inspection block is detached therefrom, which contributes to cost reduction and footprint reduction of a substrate processing system as a whole. Further, the inspection block can be shared between a plurality of substrate processing apparatuses.

Preferably, according to a second aspect of the combined system of functional blocks of the present invention, in the combined system of functional blocks of the first aspect, the first edge structure has a substrate holding part as a partial protrusion from an edge surface of a corresponding block, the second edge structure has a recess as a partial depression of an edge surface of a corresponding block, and coupling between the first and second edge structures causes the substrate holding part to be inserted into the recess of the second edge structure. As a result, a substrate transport mechanism in the processing block to which the second edge structure belongs is allowed to be easily accessible to the substrate holding part.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of an exemplary configuration of a substrate processing apparatus according to a preferred embodiment of the present invention;

FIGS. 2A and 2B each show a transport robot;

FIG. 3 is a sectional view of the configuration of an inspection block according to the preferred embodiment;

FIG. 4 shows mechanical classification of processing blocks in the substrate processing apparatus according to the preferred embodiment;

FIGS. 5 and 6 respectively show modifications of the preferred embodiment; and

FIG. 7 shows the configuration of a conventional substrate processing apparatus.

### DESCRIPTION OF THE PREFERRED EMBODIMENTS

<Configuration of Substrate Processing Apparatus>

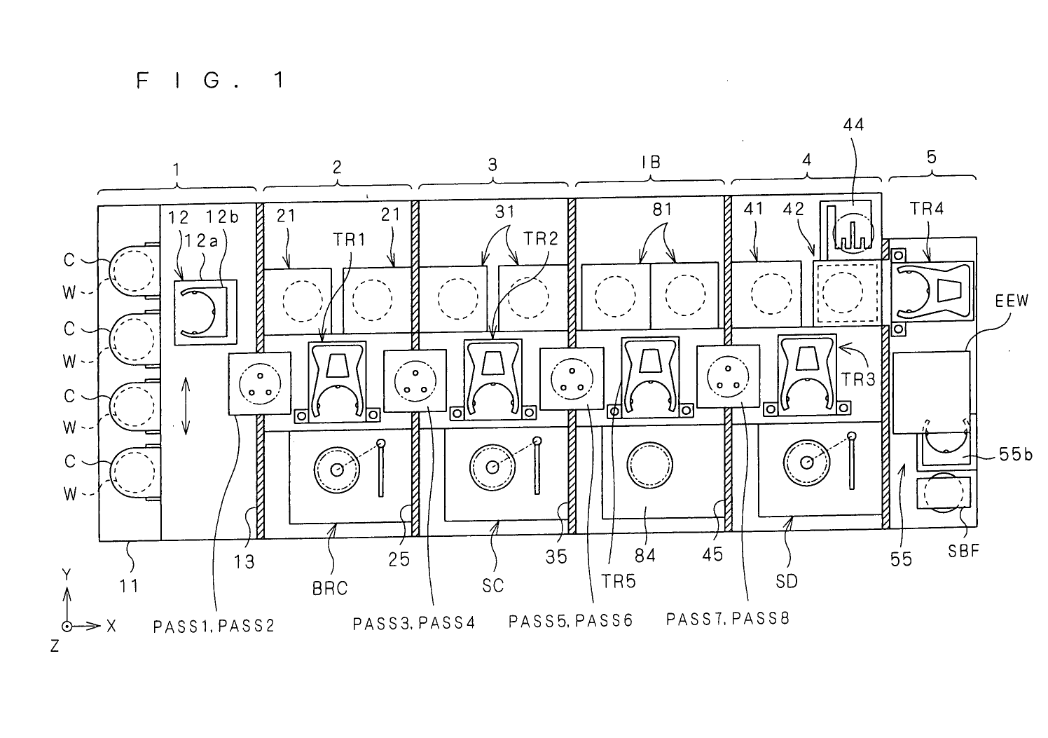

FIG. 1 is a plan view of an exemplary configuration of a substrate processing apparatus according to a preferred embodiment of the present invention. The substrate processing apparatus of the preferred embodiment serves to form an anti-reflection film and a photoresist film on a substrate such as a semiconductor wafer, and to perform development on a substrate after pattern exposure. In the present invention, a substrate to be processed in the substrate processing apparatus is not limited to a semiconductor wafer. As an example, an objective substrate may be a glass substrate for a liquid crystal display. Processes performed in the substrate processing apparatus of the present invention are not limited to formation of a film coating and development. Alternative processes such as etching and cleaning may be performed therein.

The substrate processing apparatus of the present preferred embodiment comprises a juxtaposition of six processing blocks (functional blocks) functioning in respective ways including an indexer block 1, a BARC (bottom anti-reflection coating) block 2, a resist coating block 3, a development block 4, an interface block 5 and an inspection block IB. An exposure device (stepper) as an external device not forming the substrate processing apparatus of the present preferred embodiment is connected to the interface block 5.

The inspection block IB can be arranged at any position as long as the inspection block IB is located between adjacent ones of the indexer block 1, the BARC block 2, the resist coating block 3 and the development block 4. Preferably, the location of the inspection block IB is suitably determined in accordance with the substrate inspection performed in the inspection block IB. If no substrate inspection is required, the inspection block IB may be detached from the substrate processing apparatus of FIG. 1.

According to an exemplary layout of the present preferred embodiment shown in FIG. 1, the indexer block 1, the BARC block 2, the resist coating block 3, the inspection block IB, the development block 4 and the interface block 5 are arranged in this order in a direction from the indexer block 1 toward the interface block 5.

The indexer block 1 comprises a table 11 for placing thereon a plurality of (in the present preferred embodiment, four) carriers C in a row, and a substrate transfer mechanism 12 for taking out an unprocessed substrate W from each one of the carriers C and receiving a processed substrate W to return the same to each carrier C. The substrate transfer mechanism 12 includes a movable table 12a horizontally movable along the table 11 (along a Y direction shown in FIG. 1), and a holding arm 12b provided over the movable table 12a for holding a substrate W in a horizontal position. The holding arm 12b is capable of moving in a vertical direction (in a Z direction), pivoting within a horizontal plane, and moving back and forth in a direction of the pivot radius on the table 12a. The holding arm 12b is thus accessible to each one of the carriers C, whereby the substrate transfer mechanism 12 is allowed to take out an unprocessed substrate W from the carrier C, and receive a processed substrate W to return the same to the carrier C. The carrier C may be an FOUP (front opening unified pod) for storing a substrate W in an enclosed space, an SMIF (standard mechanical interface) pod, an OC (open cassette) for holding a substrate W therein exposed to outside air, or the like.

The boundary between the indexer block 1 and the BARC block 2 adjacent to each other is provided with a partition 13 which serves to provide atmospheric isolation between the indexer block 1 and the BARC block 2. The partition 13 is provided with a vertical stack of upper and lower substrate holding parts PASS1 and PASS2 each placing thereon a substrate W for transferring a substrate W between the indexer block 1 and the BARC block 2. The substrate holding parts PASS1 and PASS2 partially penetrate the partition 13.

The upper substrate holding part PASS1 is intended for transport of a substrate W from the indexer block 1 to the BARC block 2. The substrate holding part PASS1 has three support pins for placing thereon an unprocessed substrate W taken out from the carrier C by the substrate transfer mechanism 12 in the indexer block 1. The substrate W placed on the substrate holding part PASS1 is transferred to a transport robot TR1 in the BARC block 2 discussed below. The lower substrate holding part PASS2 is intended for transport of a substrate W from the BARC block 2 to the indexer block 1. The substrate holding part PASS2 also has three support pins for placing thereon a processed substrate W transferred from the transport robot TR1 in the BARC block 2. The substrate W placed on the substrate holding part PASS2 is transferred to the substrate transfer mechanism 12 to be stored in the carrier C. That is, the substrate holding parts PASS1 and PASS2 are each accessible from both the substrate transfer mechanism 12 in the indexer block 1 and the transport robot TR1 in the BARC block 2 for transfer and receipt of a substrate W.

Substrate holding parts PASS3 through PASS8 to be discussed later, and the substrate holding parts PASS1 and PASS2 have the same structure.

The BARC block 2 is responsible for formation of an anti-reflection film underlying a resist film to reduce standing waves or halation occurring during exposure. The BARC block 2 comprises an underlayer coating processor BRC for forming an anti-reflection film on the surface of a substrate W, two thermal processing towers 21 responsible for thermal process required for formation of an anti-reflection film, and the transport robot TR1 for transferring and receiving a substrate W to and from the underlayer coating processor BRC and the thermal processing towers 21.

In the BARC block 2, the underlayer coating processor BRC and the thermal processing towers 21 are respectively positioned on the front side and the rear side of the substrate processing apparatus, while being opposed from each other with the transport robot TR1 held therebetween. The front side of the thermal processing towers 21 is provided with a thermal barrier not shown. The space between the underlayer coating processor BRC and the thermal processing towers 21, and provision of the thermal barrier serve to avoid thermal effect on the underlayer coating processor BRC caused by the thermal processing towers 21.

The underlayer coating processor BRC has a vertical stack of a plurality of coating processing units of the same structure. The thermal processing towers 21 each have a vertical stack of a plurality of hot plates for heating a substrate W to a predetermined temperature, and a plurality of cool plates for cooling a heated substrate W to a predetermined temperature and maintaining the cooled substrate W at this temperature.

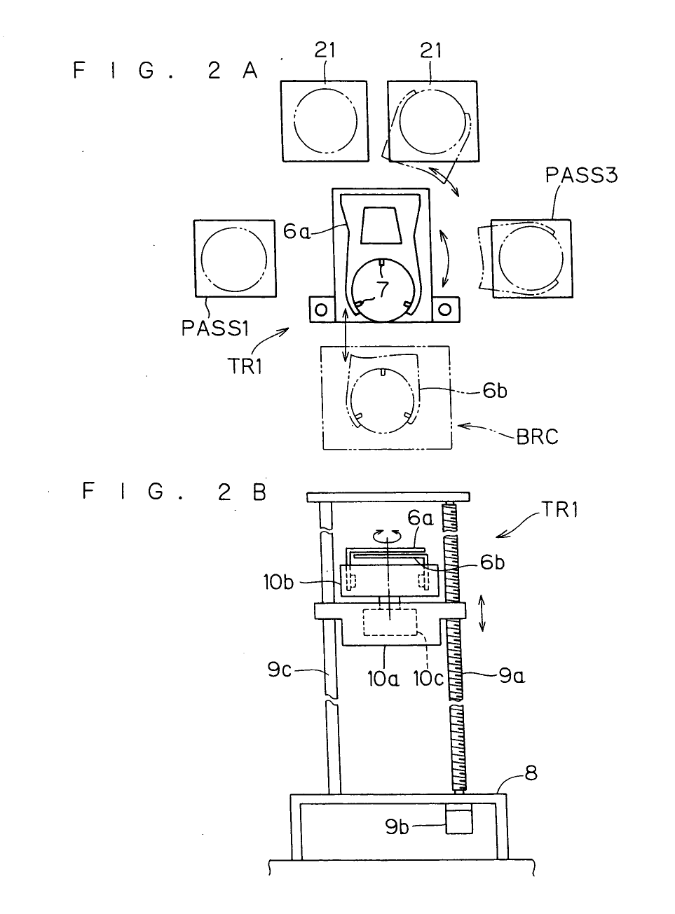

FIGS. 2A and 2B are respectively a plan view and a front view of the transport robot TR1. The transport robot TR1 has two arms 6a and 6b in close proximity in a vertical direction for holding a substrate W in a substantially horizontal position. The holding arms 6a and 6b each have a distal end portion which is “C-shaped” in plan view with a plurality of pins 7 projecting inwardly therefrom. The pins 7 serve to support the periphery of a substrate W from underneath.

The transport robot TR1 has a base 8 fixed to the base (frame) of the substrate processing apparatus. A guide shaft 9c and a rotatable screw shaft 9a are provided in upright posture on the base 8. A motor 9b is fixed to the base 8 for causing rotative movement of the screw shaft 9a. An up and down table 10a is threadedly engaged with the screw shaft 9a while being slidable with respect to the guide shaft 9c. By means of rotative movement of the screw shaft 9a caused by the motor 9b, the up and down table 10a is thus guided by the guide shaft 9c to move vertically (in the Z direction).

Provided on the up and down table 10a is an arm base 10b which is pivotable about an axis in a vertical direction. The up and down table 10a contains therein a motor 10c for causing pivoting of the arm base 10b. The two holding arms 6a and 6b are vertically arranged over the arm base 10b. By means of a sliding mechanism provided on the arm base 10b (not shown), the holding arms 6a and 6b are allowed to independently move back and forth in a horizontal direction (in a direction of the pivot radius of the arm base 10b).

With reference to FIG. 2A, the two holding arms 6a and 6b thereby independently make access to the substrate holding parts PASS1 and PASS2, to the thermal processing units of the thermal processing towers 21, to the coating processing units of the underlayer coating processor BRC and to the substrate holding parts PASS3 and PASS4 discussed below, whereby the transport robot TR1 is allowed to transfer and receive a substrate W to and from these parts.

The resist coating block 3 is arranged between the BARC block 2 and the inspection block IB. The boundary between the resist coating block 3 and the BARC block 2 is provided with a partition 25 which serves to provide atmospheric isolation between the resist coating block 3 and the BARC block 2. The partition 25 is provided with a vertical stack of the upper and lower substrate holding parts PASS3 and PASS4 each placing thereon a substrate W for transferring a substrate W between the BARC block 2 and the resist coating block 3. The substrate holding parts PASS3 and PASS4 are the same in structure as the substrate holding parts PASS1 and PASS2 discussed above. The substrate holding parts PASS3 and PASS4 partially penetrate the partition 25.

The upper substrate holding part PASS3 is intended for transport of a substrate W from the BARC block 2 to the resist coating block 3. A substrate W transferred onto the substrate holding part PASS3 by the transport robot TR1 in the BARC block 2 is transferred to a transport robot TR2 in the resist coating block 3. The lower substrate holding part PASS4 is intended for transport of a substrate W from the resist coating block 3 to the BARC block 2. A substrate W transferred onto the substrate holding part PASS4 by the transport robot TR2 in the resist coating block 3 is transferred to the transport robot TR1 in the BARC block 2. That is, the substrate holding parts PASS3 and PASS4 are each accessible from both the transport robot TR1 in the BARC block 2 and the transport robot TR2 in the resist coating block 3.

The resist coating block 3 is responsible for formation of a photoresist film on a substrate W coated with an anti-reflection film at the BARC block 2. The present preferred embodiment uses a chemically amplified resist as a photoresist. The resist coating block 3 comprises a resist coating processor SC for forming a photoresist film on an anti-reflection film as an underlying layer, two thermal processing towers 31 responsible for thermal process required for resist coating, and the transport robot TR2 for transferring and receiving a substrate W to and from the resist coating processor SC and the thermal processing towers 31.

The resist coating processor SC has a vertical stack of a plurality of coating processing units of the same structure. The thermal processing towers 31 each have a vertical stack of a plurality of hot plates for heating a substrate W to a predetermined temperature, and a plurality of cool plates for cooling a heated substrate W to a predetermined temperature and maintaining the cooled substrate W at this temperature.

The transport robot TR2 has a configuration exactly the same as that of the transport robot TR1. Two holding arms of the transport robot TR2 hence independently make access to the substrate holding parts PASS3 and PASS4, to the thermal processing units of the thermal processing towers 31, to the coating processing units of the resist coating processor SC and to the substrate holding parts PASS5 and PASS6 discussed below, whereby the transport robot TR2 is allowed to transfer and receive a substrate W to and from these parts.

The inspection block IB is arranged between the resist coating block 3 and the development block 4. The boundary between the resist coating block 3 and the inspection block IB is provided with a partition 35 which serves to provide atmospheric isolation between the resist coating block 3 and the inspection block IB. The partition 35 is provided with a vertical stack of the upper and lower substrate holding parts PASS5 and PASS6 each placing thereon a substrate W for transferring a substrate W between the resist coating block 3 and the inspection block IB. The substrate holding parts PASS5 and PASS6 are the same in structure as the substrate holding parts PASS1 and PASS2 discussed above. The substrate holding parts PASS5 and PASS6 partially penetrate the partition 35.

The upper substrate holding part PASS5 is intended for transport of a substrate W from the resist coating block 3 to the inspection block IB. A substrate W transferred onto the substrate holding part PASS5 by the transport robot TR2 in the resist coating block 3 is transferred to a transport robot TR5 (inspection-specific substrate transport mechanism) in the inspection block IB. The lower substrate holding part PASS6 is intended for transport of a substrate W from the inspection block IB to the resist coating block 3. A substrate W transferred onto the substrate holding part PASS6 by the transport robot TR5 in the inspection block IB is transferred to the transport robot TR2 in the resist coating block 3. That is, the substrate holding parts PASS5 and PASS6 are each accessible from both the transport robot TR2 in the resist coating block 3 and the transport robot TR5 in the inspection block IB.

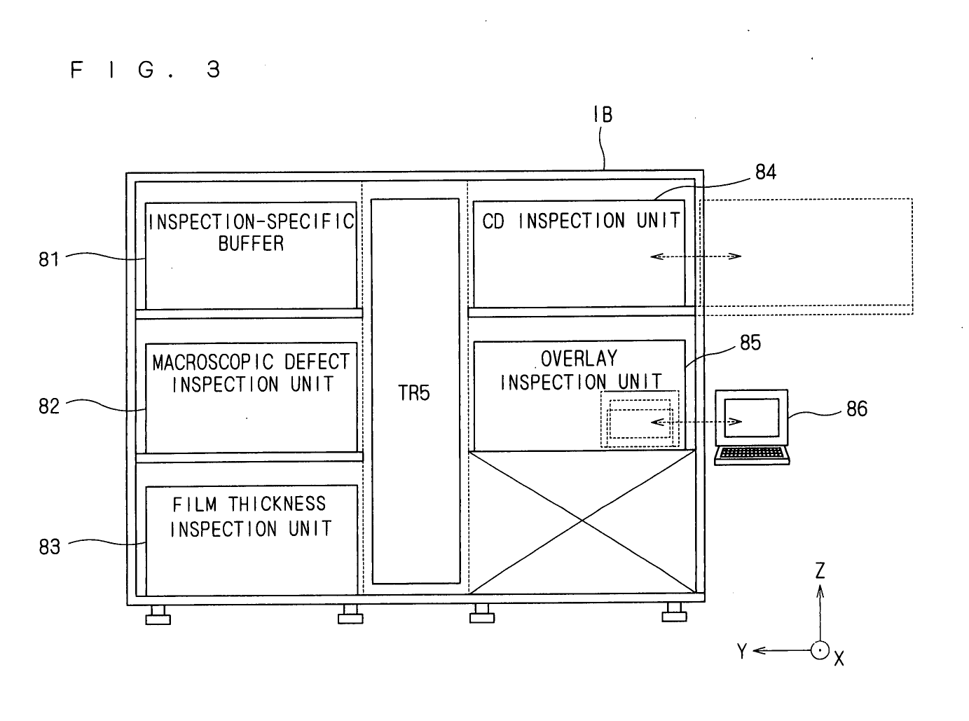

The inspection block IB is responsible for predetermined substrate inspection of a substrate W after being subjected to, or midway through a series of photolithography process steps. FIG. 3 is a sectional view of the configuration of the inspection block IB. The X, Y and Z directions shown in FIG. 3 correspond to those shown in FIG. 1. The inspection block IB comprises an inspection-specific buffer 81, substrate inspection units responsible for predetermined substrate inspections including a macroscopic defect inspection unit 82, a film thickness inspection unit 83, a CD inspection unit 84 and an overlay inspection unit 85, the transport robot TR5 for transferring and receiving a substrate W to and from the inspection-specific buffer 81 and these substrate inspection units, and an inspection-specific operating part 86 for controlling each of the substrate inspection units. The transport robot TR5 has a configuration exactly the same as those of the transport robots TR1 and TR2.

The macroscopic defect inspection unit 82 has a macroscopic defect inspection device for optically detecting a relatively large defect appearing on a substrate W such as particles or unevenness in an applied resist. The film thickness inspection unit 83 has a film thickness measuring device for optically measuring and inspecting the film thickness of a resist applied on a substrate W. The CD inspection unit 84 has a line width measuring device for optically measuring and inspecting the line width of a pattern formed on a substrate W after being subjected to development. The overlay inspection unit 85 is responsible for overlay inspection between the upper layer portion and the lower layer portion of a resist pattern by optically detecting alignment marks formed on a substrate W, for example.

With reference to FIG. 3, the CD inspection unit 84 is allowed to slide horizontally to be pulled out of the casing frame of inspection block IB to the outside in the Y direction. Although not shown, the inspection-specific buffer 81, the macroscopic defect inspection unit 82 and the film thickness inspection unit 83 are each allowed to slide horizontally (in the X direction) within the casing frame of the inspection block IB. Such a configuration of each substrate inspection unit facilitates maintenance of the inspection block IB.

The inspection-specific buffer 81 is arranged in two columns in the upper section of the inspection block IB. The inspection-specific buffer 81 has a cabinet capable of storing a plurality of substrates W in tiers. When a substrate W is being subjected to inspection at any one of the macroscopic defect inspection unit 82, the film thickness inspection unit 83 or the CD inspection unit 84, the inspection-specific buffer 81 temporarily stores a subsequent substrate W to be subjected to inspection at the same inspection unit.

The inspection-specific operating part 86 has a configuration of an ordinary computer with a monitor and a keyboard. With reference to FIG. 3, the inspection-specific operating part 86 can be folded in two to be stored in the inspection block IB in the event of automatic substrate inspection which requires no operation of the inspection-specific control operating part 86, for example.

In the present preferred embodiment, the operator of the substrate processing apparatus of FIG. 1 is allowed to control inspection to be performed in each one of the substrate inspection units by way of the inspection-specific operating part 86. As discussed, the inspection block IB can be arranged at any position as long as the inspection block IB is located between adjacent ones of the indexer block 1, the BARC block 2, the resist coating block 3 and the development block 4. As the inspection block IB comprises the inspection-specific operating part 86 dedicated to itself, the operator is always allowed to control operation of each of the substrate inspection units near the inspection block IB even when arrangement of the inspection block IB is changed in the substrate processing apparatus. Naturally, the inspection-specific operating part 86 dedicated to the inspection block IB may be removed, in which case the main operating portion of the substrate processing apparatus is responsible for control of the inspection block IB. As an example, when the substrate processing apparatus is controlled by one operator, the main controller is capable of handling the overall control of the apparatus including the inspection block IB.

The arrangement of the inspection-specific buffer 81, the macroscopic defect inspection unit 82, the film thickness inspection unit 83, the CD inspection unit 84 and the overlay inspection unit 85 is not limited to the one shown in FIG. 3. They may be shifted in the inspection block IB. Further, these units may each be allowed to be pulled out of the casing frame of the inspection block IB to the outside in the Y direction, or alternatively, to slide horizontally (in the X direction). The location indicated by a cross mark (X) in FIG. 3 is occupied by a power supply unit, controller and the like dedicated to the inspection block IB, or it is reserved as empty space for future provision of another substrate inspection unit.

The transport robot TR5 has a configuration exactly the same as that of the transport robot TR1. Two holding arms of the transport robot TR5 hence independently make access to the substrate holding parts PASS5 and PASS6, to the inspection-specific buffer 81, to the macroscopic defect inspection unit 82, to the film thickness inspection unit 83, to the CD inspection unit 84 and to the substrate holding parts PASS7 and PASS8 discussed below, whereby the transport robot TR5 is allowed to transfer and receive a substrate W to and from these parts.

The development block 4 is arranged between the inspection block IB and the interface block 5. The boundary between the inspection block IB and the development block 4 is provided with a partition 45 which serves to provide atmospheric isolation between the inspection block IB and the development block 4. The partition 45 is provided with a vertical stack of the upper and lower substrate holding parts PASS7 and PASS8 each placing thereon a substrate W for transferring a substrate W between the inspection block IB and the development block 4. The substrate holding parts PASS7 and PASS8 are the same in structure as the substrate holding parts PASS1 and PASS2 discussed above. The substrate holding parts PASS7 and PASS8 partially penetrate the partition 45.

The upper substrate holding part PASS7 is intended for transport of a substrate W from the inspection block IB to the development block 4. A substrate W transferred onto the substrate holding part PASS7 by the transport robot TR5 in the inspection block IB is transferred to a transport robot TR3 in the development block 4. The lower substrate holding part PASS8 is intended for transport of a substrate W from the development block 4 to the inspection block IB. A substrate W transferred onto the substrate holding part PASS8 by the transport robot TR3 in the development block 4 is transferred to the transport robot TR5 in the inspection block IB. That is, the substrate holding parts PASS7 and PASS8 are each accessible from both the transport robot TR5 in the inspection block IB and the transport robot TR3 in the development block 4.

The development block 4 is responsible for development of a substrate W after being subjected to exposure. The development block 4 comprises a development processor SD for supplying a developing solution onto a substrate W patterned by exposure to develop the substrate W, two thermal processing towers 41 and 42 responsible for thermal process required for development, and the transport robot TR3 for transferring and receiving a substrate W to and from the development processor SD and the thermal processing towers 41 and 42. The transport robot TR3 has a configuration exactly the same as that of the transport robot TR1.

The development processor SD has a vertical stack of a plurality of development processing units of the same structure. The thermal processing tower 41 which is the closer to the indexer block 1 has a vertical stack including a plurality of hot plates for heating a substrate W to a predetermined temperature, and a plurality of cool plates for cooling a heated substrate W to a predetermined temperature and maintaining the cooled substrate W at this temperature. The thermal processing tower 42 which is the farther from the indexer block 1 has a vertical stack including a plurality of heaters and a plurality of cool plates. The heaters of the thermal processing tower 42 each include an ordinary hot plate, a temporary substrate holding part accompanying the hot plate for placing thereon a substrate W at a position spaced from the hot plate, and a local transport mechanism 44 for transferring a substrate W between the hot plate and the temporary substrate holding part.

The temporary substrate holding part of each one of the heaters of the thermal processing tower 42 is opened on the side of a transport robot TR4 in the interface block 5, whereas it is closed on the side of the transport robot TR3 in the development block 4. That is, the heaters of the thermal processing tower 42 are accessible from the transport robot TR4 in the interface block 5, whereas they are inaccessible from the transport robot TR3 in the development block 4. The transport robot TR3 in the development block 4 is accessible to the thermal processing units of the thermal processing tower 41.

The interface block 5 adjacent to the development block 4 is responsible for transfer of a substrate W to and from the exposure device as an external device not forming the substrate processing apparatus of the present preferred embodiment. The interface block 5 of the present preferred embodiment comprises a transport mechanism 55 for transferring a substrate W to and from the exposure device, two edge exposure units EEW for exposing the periphery of a substrate W coated with a photoresist film, and the transport robot TR4 for transferring and receiving a substrate W to and from the heaters in the development block 4 and the edge exposure units EEW.

The two edge exposure units EEW are arranged in vertically stacked relation in the center of the interface block 5. The transport robot TR4 has the same configuration as the foregoing transport robot TR1.

The foregoing indexer block 1, the BARC block 2, the resist coating block 3, the development block 4, the interface block 5 and the inspection block IB are constantly supplied with a downflow of clean air, which prevents adverse effects of raised particles and gas flows upon the process in each block. Further, each block is held at a slightly positive pressure inside relative to the outside to prevent entry of particles and contaminants.

<Boundary Structure for Substrate Transfer Between Processing Blocks>

The inspection block IB can be arranged at any position as long as the inspection block IB is located between adjacent ones of the indexer block 1, the BARC block 2, the resist coating block 3 and the development block 4. When no substrate inspection is required, the inspection block IB can be detached from the substrate processing apparatus shown in FIG. 1. To realize such arrangement of the inspection block IB, the substrate processing apparatus features a boundary structure for substrate transfer between the processing blocks as follows.

As seen from the foregoing, all the transfer of a substrate W between the indexer block 1, the BARC block 2, the resist coating block 3, the development block 4 and the inspection block IB is handled by the substrate holding parts (PASS1 through PASS8) operative to function as interfaces therefor.

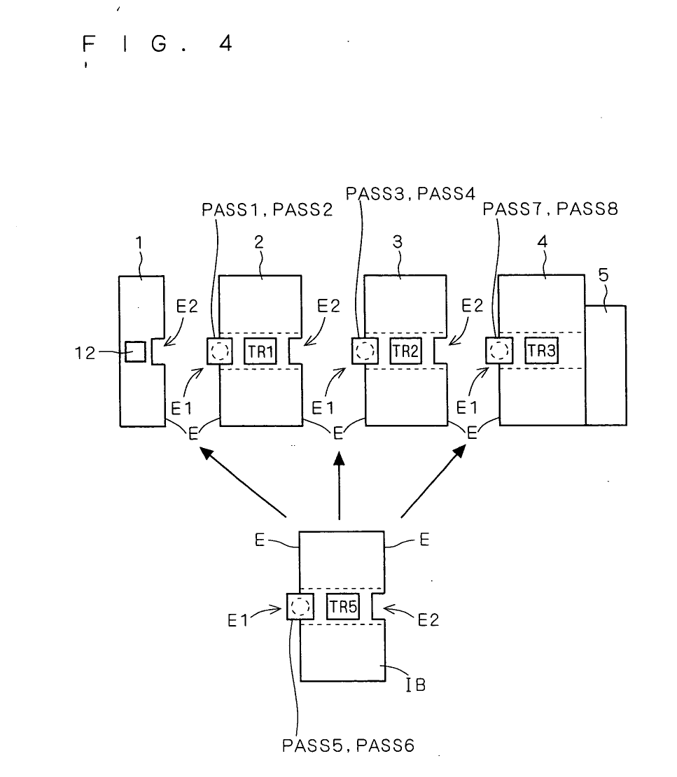

In the substrate processing apparatus of the present preferred embodiment, the processing blocks are mechanically classified in the following way: the substrate holding parts PASS1 and PASS2 are classified as part of the BARC block 2, the substrate holding parts PASS3 and PASS4 are classified as part of the resist coating block 3, the substrate holding parts PASS5 and PASS6 are classified as part of the inspection block IB, and the substrate holding parts PASS7 and PASS8 are classified as part of the development block 4. This classification is realized by an exemplary way as follows: the substrate holding parts PASS1 and PASS2 are mounted to the casing frame of the BARC block 2, PASS3 and PASS4 are mounted to the casing frame of the resist coating block 3, PASS5 and PASS6 are mounted to the casing frame of the inspection block IB, and PASS7 and PASS8 are mounted to the casing frame of the development block 4. As a result, the substrate processing apparatus of the present preferred embodiment is mechanically divided into five functional blocks as shown in FIG. 4.

Namely, in the present preferred embodiment, the BARC block 2 comprises the transport robot TR1 and the substrate holding parts PASS1 and PASS2 as a substrate transport mechanism. The resist coating block 3 comprises the transport robot TR2 and the substrate holding parts PASS3 and PASS4 as a substrate transport mechanism. The inspection block IB comprises the transport robot TR5 and the substrate holding parts PASS5 and PASS6 as a substrate transport mechanism. The development block 4 comprises the transport robot TR3 and the substrate holding parts PASS7 and PASS8 as a substrate transport mechanism.

As discussed, in the configuration shown in FIG. 1, the substrate holding parts PASS1 and PASS2 are accessible from the substrate transfer mechanism 12 and the transport robot TR1. The substrate holding parts PASS3 and PASS4 are accessible from the transport robots TR1 and TR2. The substrate holding parts PASS5 and PASS6 are accessible from the transport robots TR2 and TR5. The substrate holding parts PASS7 and PASS8 are accessible from the transport robots TR3 and TR5. The substrate holding parts PASS 1 through PASS8 all have the same structure.

With reference to FIG. 4, butt joints between the functional blocks are referred to as “edges E”. The edges E include edge structures (first edge structures) E1 with substrate holding parts, and edge structures (second edge structures) E2 with no substrate holding part.

That is, in the present preferred embodiment, the indexer block 1 has the second edge structure E2. The BARC block 2, the resist coating block 3 and the inspection block IB each have both the first and second edge structures E1 and E2. The development block 4 has the first edge structure E1. Butt joints between the functional blocks complementarily connect the first and second edge structures E1 and E2, thereby realizing a certain boundary structure for substrate transfer as shown in FIG. 1.

The substrate holding parts PASS1 and PASS8 all have the same structure, which means the respective first edge structures E1 of the functional blocks are of the same structure, thereby complementarily providing sameness of the respective second edge structures E2 of the functional blocks. The first and second edge structures E1 and E2 are hence attached to or detached from each other while being complementarily coupled to each other by a butt joint between the functional blocks, whereby a certain boundary structure for substrate transfer is realized in the substrate processing apparatus.

By way of example, it is assumed that the inspection block IB (including the substrate holding parts PASS5 and PASS6) is detached from the configuration of FIG. 1, and hence the development block 4 (including the substrate holding parts PASS7 and PASS8) is directly connected to the resist coating block 3. The substrate holding parts PASS7 and PASS 8 are the same in structure as the substrate holding parts PASS5 and PASS6, whereby the transport robot TR2 in the resist coating block 3 is accessible to the substrate holding parts PASS7 and PASS8 of the development block 4 adjacent to the resist coating block 3. The transport robots TR2 and TR3 are hence allowed to transfer a substrate W therebetween by way of the substrate holding parts PASS7 and PASS8. That is, direct connection between the resist coating block 3 and the development block 4 allows transfer of a substrate W therebetween.

Next, it is assumed that the detached inspection block IB is interposed between the indexer block 1 and the BARC block 2 (including the substrate holding parts PASS1 and PASS2). The substrate holding parts PASS5 and PASS6 are the same in structure as the substrate holding parts PASS1 and PASS2, whereby the substrate transfer mechanism 12 in the indexer block 1 is accessible to the substrate holding parts PASS5 and PASS6 of the inspection block IB adjacent to the indexer block 1. The substrate transfer mechanism 12 and the transport robot TR5 are hence allowed to transfer a substrate W therebetween by way of the substrate holding parts PASS5 and PASS6. Further, the substrate holding parts PASS1 and PASS2 are the same in structure as the substrate holding parts PASS7 and PASS8, whereby the transport robot TR5 in the inspection block IB is accessible to the substrate holding parts PASS1 and PASS2 of the BARC block 2 adjacent to the inspection block IB. The transport robots TR5 and TR1 are hence allowed to transfer a substrate W therebetween by way of the substrate holding parts PASS1 and PASS2. In this case, transfer of a substrate W is allowed between the indexer block 1 and the inspection block IB, and between the inspection block IB and the BARC block 2.

The detached inspection block IB can alternatively be interposed between the BARC block 2 and the resist coating block 3 according to the same theory, in which case transfer of a substrate W is allowed between the BARC block 2 and the inspection block IB, and between the inspection block IB and the resist coating block 3.

That is, in the arrangement in which the inspection block IB is located at an arbitrary position between adjacent ones of the indexer block 1, the BARC block 2, the resist coating block 3 and the development block 4 as shown in FIG. 4, the present preferred embodiment allows transfer of a substrate W between the inspection block IB and the processing block adjacent thereto. Flexibility of layout is thus enhanced in the substrate processing apparatus, and throughput improvement is realized by layout change to be responsive to the object of substrate inspection or to a substrate process flow, for example. As a result of enhanced flexibility, layout responsive to user's request can be easily realized.

As an example, it is assumed that the arrangement of FIG. 1 is employed in which the indexer block 1, the BARC block 2, the resist coating block 3, the inspection block IB, the interface block 5 and the exposure device are arranged in this order in a direction from the indexer block 1 toward the exposure device. According to this arrangement, a substrate W follows a path starting from the indexer block 1, then entering the BARC block 2 (for formation of an anti-reflection film), the resist coating block 3 (for resist coating), the inspection block IB (for inspection after resist coating), the development block 4, the interface block 5 and the exposure device (for exposure), thereafter reentering the interface block 5, the development block 4 (for development), the inspection block IB (for inspection after exposure), the resist coating block 3 and the BARC block 2, finally returning to the indexer block 1. That is, a substrate W can be subjected to both the inspection after resist coating and the inspection after exposure, without going against the flow of transport starting from the indexer block 1, then moving forward to reach the exposure device, thereafter returning to the indexer block 1.

When substrate inspection only requires inspection after exposure, the indexer block 1, the inspection block IB, the BARC block 2, the resist coating block 3, the development block 4, the interface block 5 and the exposure device may be arranged in this order in a direction from the indexer block 1 toward the exposure device. According to this arrangement, a substrate W follows a path starting from the indexer block 1, then entering the inspection block IB, the BARC block 2 (for formation of an anti-reflection film), the resist coating block 3 (for resist coating), the development block 4, the interface block 5 and the exposure device (for exposure), thereafter reentering the interface block 5, the development block 4 (for development), the resist coating block 3, the BARC block 2 and the inspection block IB (for inspection after exposure), finally returning to the indexer block 1. That is, a substrate W can be subjected to the inspection after exposure without going against the foregoing flow of transport.

Alternatively, the indexer block 1, the BARC block 2, the inspection block IB, the resist coating block 3, the development block 4, the interface block 5 and the exposure device may be arranged in this order in a direction from the indexer block 1 toward the exposure device. This arrangement also allows a substrate W to be subjected to the inspection after exposure without going against the foregoing flow of transport.

Still alternatively, a plurality of inspection blocks IB can be arranged in the same substrate processing apparatus. As an example, a first inspection block IB1 responsible for inspection after exposure and a second inspection block IB2 responsible for inspection after resist coating are separately prepared. In a direction from the indexer block 1 toward the exposure device, the indexer block 1, the first inspection block IB1, the BARC block 2, the resist coating block 3, the second inspection block IB2, the development block 4, the interface block 5 and the exposure device may be arranged in this order. This arrangement also allows a substrate W to be subjected to both the inspection after resist coating and the inspection after exposure, without going against the foregoing flow of transport.

When substrate inspection is not required, the inspection block IB (including the substrate holding parts PASS5 and PASS6) can be detached from the configuration of FIG. 1 to directly connect the resist coating block 3 and the development block 4. This arrangement contributes to cost reduction and footprint reduction of a substrate processing system as a whole. Further, the detached inspection block IB is still operable when incorporated into another substrate processing apparatus, which means the inspection block IB can be shared between a plurality of substrate processing apparatuses. As a result, cost reduction of a system as a whole is realized.

In the present preferred embodiment, the first edge structures E1 have substrate holding parts (PASS1 through PASS8) as partial protrusions from the edge surfaces of the corresponding blocks, and the second edge structures E2 have recesses as partial depressions of the edge surfaces of the corresponding blocks. The coupling between the first and second edge structures E1 and E2 causes the substrate holding part to be inserted into the recess of the second edge structure E2, which advantageously allows the substrate transport mechanism in the block to which this edge structure E2 belongs (the substrate transfer mechanism 12 and the transport robots TR1 through TR5) to be easily accessible to the substrate holding part.

In the foregoing arrangement of the substrate processing apparatus, four processing blocks including the indexer block 1, the BARC block 2, the resist coating block 3 and the development block 4, or five functional blocks including these four processing blocks and the inspection block IB, are connected by butt joints. However, the applicability of the present invention is not limited to this configuration. As long as the butt joints between these four processing blocks, and the butt joint between each processing block and the inspection block IB are each formed by the connection of the first and second edge structures E1 and E2 as a pair, an arbitrary combination is applicable including two or more of the plurality of substrate processing blocks and the substrate inspection block.

<Modifications>

In the foregoing description of the preferred embodiment, the processing blocks of the substrate processing apparatus are mechanically classified as shown in FIG. 4. That is, the substrate holding parts PASS1 and PASS2 are classified as part of the BARC block 2, the substrate holding parts PASS3 and PASS4 are classified as part of the resist coating block 3, the substrate holding parts PASS5 and PASS6 are classified as part of the inspection block IB, and the substrate holding parts PASS7 and PASS8 are classified as part of the development block 4. However, the applicability of the present invention is not limited to this classification.

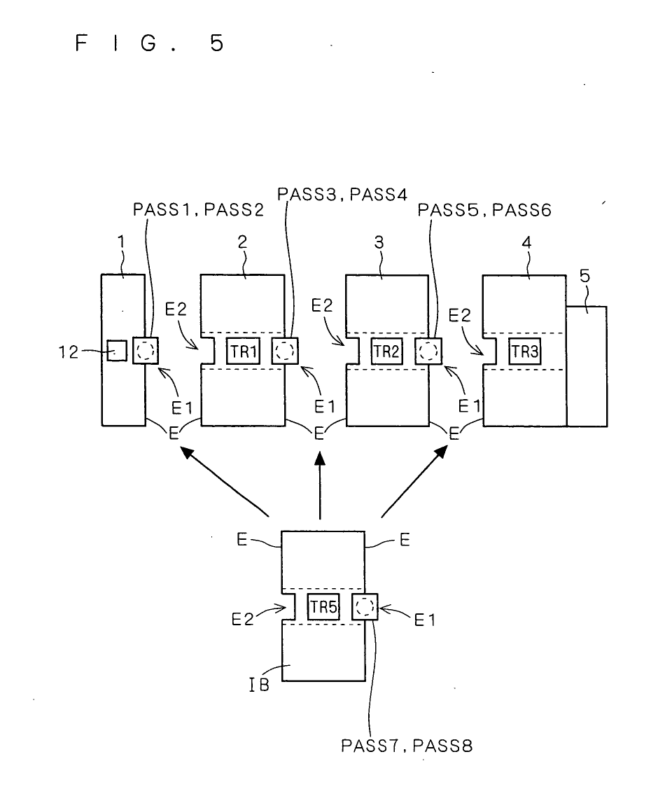

As an example, with reference to FIG. 5, the substrate holding parts PASS1 and PASS2 are classified as part of the indexer block 1, the substrate holding parts PASS3 and PASS4 are classified as part of the BARC block 2, the substrate holding parts PASS5 and PASS6 are classified as part of the resist coating block 3, and the substrate holding parts PASS7 and PASS8 are classified as part of the inspection block IB. According to this classification, the indexer block 1 has the first edge structure E1. The BARC block 2, the resist coating block 3 and the inspection block IB each have both the first and second edge structures E1 and E2. The development block 4 has the second edge structure E2. According to the same theory as discussed above, the inspection block IB can be arranged at any position in this alternative classification, as long as the inspection block IB is located between adjacent ones of the indexer block 1, the BARC block 2, the resist coating block 3 and the development block 4. A substrate W can also be transferred between the inspection block IB and the processing block connected thereto. As a result, the classification shown in FIG. 5 provides the same effects as obtained in the foregoing preferred embodiment.

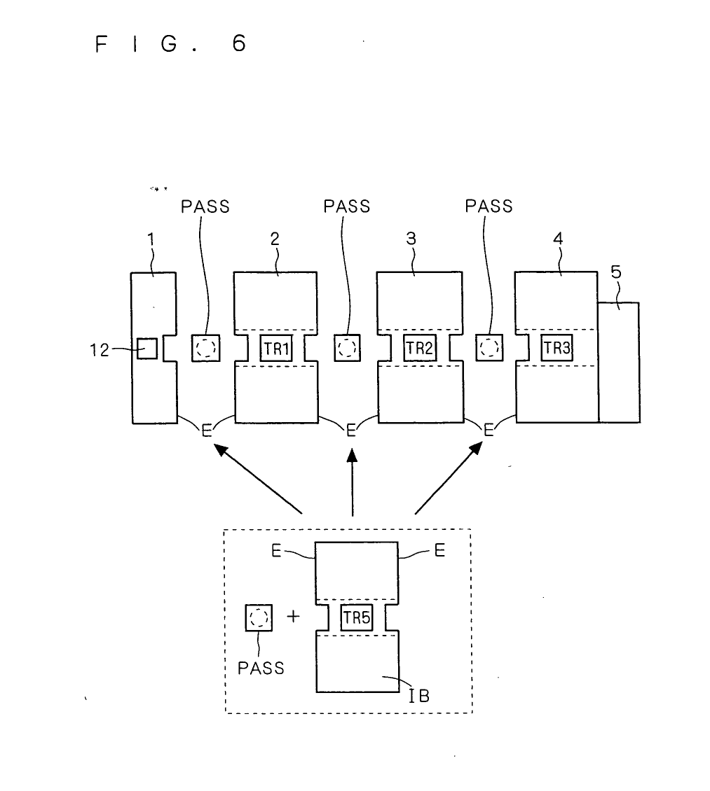

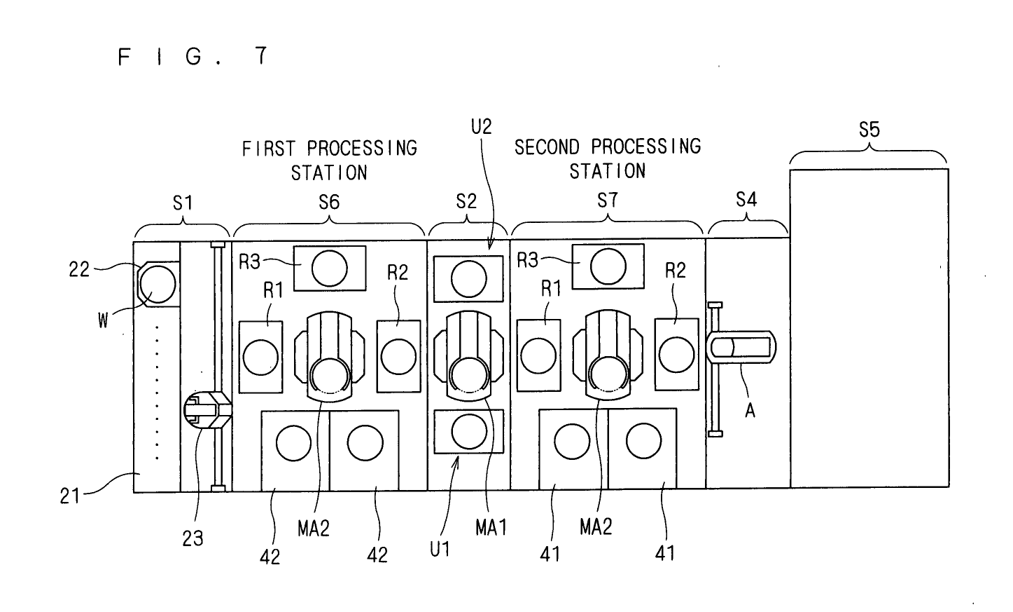

As another example, with reference to FIG. 6, the substrate holding parts PASS1 through PASS8 (which are all identified as “PASS” in FIG. 6) may be independent of the functional blocks. In this case, each edge E of each of the functional blocks may have either the first edge structure E1 or the second edge structure E2. As long as each butt joint between the functional blocks is formed by the connection of the first and second edge structures E1 and E2 as a pair, the inspection block IB can be located between any adjacent ones of the processing blocks. A substrate W can also be transferred between the inspection block IB and the functional block connected thereto. As a result, the classification shown in FIG. 6 provides the same effects as obtained in the foregoing preferred embodiment.

The substrate holding parts PASS1 through PASS8 have been described as all having the same structure. The substrate holding parts PASS1 through PASS8 may have respective structures as long as they are accessible from each substrate transport mechanism in the adjacent functional block (the substrate transfer mechanism 12 and the transport robots TR1 through TR5).

While the invention has been shown and described in detail, the foregoing description is in all aspects illustrative and not restrictive. It is therefore understood that numerous modifications and variations can be devised without departing from the scope of the invention.

1. A substrate processing apparatus, comprising:
a first substrate processing block;
a second substrate processing block; and
a substrate inspection block,
wherein at least one of said first and second substrate processing blocks, and said substrate inspection block have respective substrate transport mechanisms,
wherein a first and a second edge structures are defined which are attached to or detached from each other while being complementarily coupled to each other by a butt joint, thereby realizing a certain boundary structure for substrate transfer,
wherein a specific edge of said first substrate processing block has said first edge structure,
wherein a specific edge of said second substrate processing block has said second edge structure, and
wherein said substrate inspection block has a first edge with said first edge structure and a second edge with said second edge structure.

2. The substrate processing apparatus according to claim 1, further comprising:
an additional substrate processing block having a first edge with said first edge structure and a second edge with said second edge structure,
wherein said additional substrate processing block is interposed either between said substrate inspection block and said first substrate processing block or between said substrate inspection block and said second substrate processing block, whereby block interconnection is made by means of the butt joint between said first and second edge structures.

3. The substrate processing apparatus according to claim 1, further comprising:
a plurality of additional substrate processing blocks each having a first edge with said first edge structure and a second edge with said second edge structure,
wherein one or more of said plurality of additional substrate processing blocks are interposed either between said substrate inspection block and said first substrate processing block or between said substrate inspection block and said second substrate processing block, or both, whereby block interconnection is made by means of the butt joint between said first and second edge structures.

4. The substrate processing apparatus according to claim 1,
wherein said first edge structure has a substrate holding part arranged at a location accessible from a substrate transport mechanism when said first and second edge structures are connected, said substrate transport mechanism being contained in a block to which said second edge structure belongs.

5. The substrate processing apparatus according to claim 4,
wherein said substrate transport mechanism in said substrate inspection block includes a transport robot accessible to a substrate holding part in said first edge structure of said first substrate processing block when said first edge structure of said first substrate processing block is connected to said second edge structure of said substrate inspection block.

6. The substrate processing apparatus according to claim 1,
wherein said substrate inspection block comprises a substrate inspection unit responsible for a predetermined substrate process, and
wherein said substrate inspection unit is slidable in a horizontal direction.

7. The substrate processing apparatus according to claim 6,
wherein said substrate inspection unit can be pulled out of the casing frame of said substrate inspection block by means of the slidable movement in a horizontal direction.

8. The substrate processing apparatus according to claim 1,
wherein said substrate inspection block further comprises an inspection-specific buffer capable of temporarily storing a substrate to be subjected to inspection.

9. The substrate processing apparatus according to claim 1,
wherein said substrate inspection block further comprises an operating part for controlling substrate inspection at said substrate inspection block.

10. The substrate processing apparatus according to claim 1,
wherein either said first substrate processing block or said second substrate processing block is an indexer block for taking out an unprocessed substrate while storing a processed substrate.

11. The substrate processing apparatus according to claim 1,
wherein one of said first and second substrate processing blocks is a resist coating block for forming a resist film on a substrate, and
wherein the other one of said first and second substrate processing blocks is a development block for performing development upon a substrate.

12. A combined system of functional blocks for use in a substrate processing apparatus, comprising:
a plurality of substrate processing blocks; and
a substrate inspection block,
wherein a first and a second edge structures are defined as a pair which are attached to or detached from each other while being complementarily coupled to each other by a butt joint, thereby realizing a certain boundary structure for substrate transfer, and
wherein butt joints between said plurality of substrate processing blocks, and a butt joint between each of said plurality of substrate processing blocks and said substrate inspection block are each formed by the connection of said first and second edge structures as a pair, whereby arbitrary combination is applicable including two or more of said plurality of substrate processing blocks and said substrate inspection block.

13. The combined system of functional blocks according to claim 12,
wherein said first edge structure has a substrate holding part as a partial protrusion from an edge surface of a corresponding block,
wherein said second edge structure has a recess as a partial depression of an edge surface of a corresponding block, and
wherein coupling between said first and second edge structures causes said substrate holding part to be inserted into said recess of said second edge structure.
